(19) United States
(12) Patent Application Publication
(10) Pub. No.: US 2025/0321388 A1
(43) Pub. Date: Oct. 16, 2025

(54) ELECTRONIC DEVICE

(71) Applicant: Advanced Semiconductor Engineering, Inc., Kaohsiung (TW)

(72) Inventors: Chang Yi WU, Kaohsiung (TW); Jenchun CHEN, Kaohsiung (TW); Ya-Wen LIAO, Kaohsiung (TW); Chih-Hong LIN, Kaohsiung (TW)

(73) Assignee: Advanced Semiconductor Engineering, Inc., Kaohsiung (TW)

(21) Appl. No.: 18/633,927

(22) Filed: Apr. 12, 2024

(51) Int. Cl. G02B 6/42; H01L 23/00; H01L 25/16; H01L 25/18

(52) U.S. Cl. CPC G02B 6/4228; H01L 24/05; H01L 24/13; H01L 24/16; H01L 24/29; H01L 24/32; H01L 24/73; H01L 25/167; H01L 25/18; H01L 24/06; H01L 24/14; H01L 24/17; H01L 24/30; H01L 24/33; H01L 24/45; H01L 24/48; H01L 2224/05541; H01L 2224/0557; H01L 2224/05624; H01L 2224/05639; H01L 2224/05644; H01L 2224/05647; H01L 2224/0603; H01L 2224/13019; H01L 2224/13139; H01L 2224/13144; H01L 2224/13147; H01L 2224/1403; H01L 2224/16148; H01L 2224/16225; H01L 2224/17181; H01L 2224/29111; H01L 2224/29144; H01L 2224/2929; H01L 2224/30505; H01L 2224/32145; H01L 2224/32225; H01L 2224/33181; H01L 2224/45124; H01L 2224/45139; H01L 2224/45144; H01L 2224/45147; H01L 2224/48091; H01L 2224/48227; H01L 2224/73204; H01L 2224/73207; H01L 2224/73215; H01L 2224/73253; H01L 2224/73265; H01L 2924/0132; H01L 2924/0665; H01L 2924/07025; H01L 2924/1431

(57) ABSTRACT

An electronic device is provided. The electronic device includes a photonic component, a first optical element, and a second optical element. The photonic component includes an optical channel. The first optical element is configured to optically couple with the optical channel. The second optical element is self-aligned with the optical channel and defined at a specific position to be configured to direct an optical signal between the optical channel and the first optical element.

### BACKGROUND

### 1. Technical Field

The present disclosure relates generally to an electronic device.

### 2. Description of the Related Art

Currently, optical coupling between optical waveguides of a photonic component and optical elements in a package may be achieved by active alignments during manufacturing processes. In the active alignment process, a light source must be turned on to transmit an optical signal directly to the optical waveguides of the photonic component, and the optical signal received by the photonic component is monitored when the optical element continues changing position until an optimum optical signal is monitored by the photonic component to complete the active alignment process.

### SUMMARY

In one or more arrangements, an electronic device includes a photonic component, a first optical element, and a second optical element. The photonic component includes an optical channel. The first optical element is configured to optically couple with the optical channel. The second optical element is self-aligned with the optical channel and defined at a specific position to be configured to direct an optical signal between the optical channel and the first optical element.

In one or more arrangements, an electronic device includes an electronic component and a connecting structure. The connecting structure includes an optical element. The connecting structure is configured to solder to the electronic component and to conduct an optical transmission between the electronic component and the optical element.

In one or more arrangements, an electronic device includes a first electronic component, a second electronic component, and an optical element. The second electronic component is disposed above and electrically connected to the first electronic component. The optical element is supported by the second electronic component and configured to optically couple with the first electronic component.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a perspective view of an electronic device in accordance with some arrangements of the present disclosure.

FIG. 1B is a cross-section of an electronic device in accordance with some arrangements of the present disclosure.

FIG. 2A is a cross-section of an electronic device in accordance with some arrangements of the present disclosure.

FIG. 2B is a cross-section of an electronic device in accordance with some arrangements of the present disclosure.

FIG. 2C is a cross-section of an electronic device in accordance with some arrangements of the present disclosure.

FIG. 2D is a cross-section of an electronic device in accordance with some arrangements of the present disclosure.

FIG. 2E is a cross-section of a portion of an electronic device in accordance with some arrangements of the present disclosure.

FIG. 2F is a cross-section of a portion of an electronic device in accordance with some arrangements of the present disclosure.

FIG. 3A is a cross-section of an electronic device in accordance with some arrangements of the present disclosure.

FIG. 3B is a cross-section of an electronic device in accordance with some arrangements of the present disclosure.

FIG. 3C is a cross-section of an electronic device in accordance with some arrangements of the present disclosure.

FIG. 4A is a perspective view of an electronic device in accordance with some arrangements of the present disclosure.

FIG. 4B is a cross-section of an electronic device in accordance with some arrangements of the present disclosure.

FIG. 5A is a cross-section of an electronic device in accordance with some arrangements of the present disclosure.

FIG. 5B is a cross-section of an electronic device in accordance with some arrangements of the present disclosure.

FIG. 6A, FIG. 6B, FIG. 6C, and FIG. 6D illustrate various stages of an exemplary method for manufacturing an electronic device in accordance with some embodiments of the present disclosure.

FIG. 7A, FIG. 7B, FIG. 7C, and FIG. 7D illustrate various stages of an exemplary method for manufacturing an electronic device in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

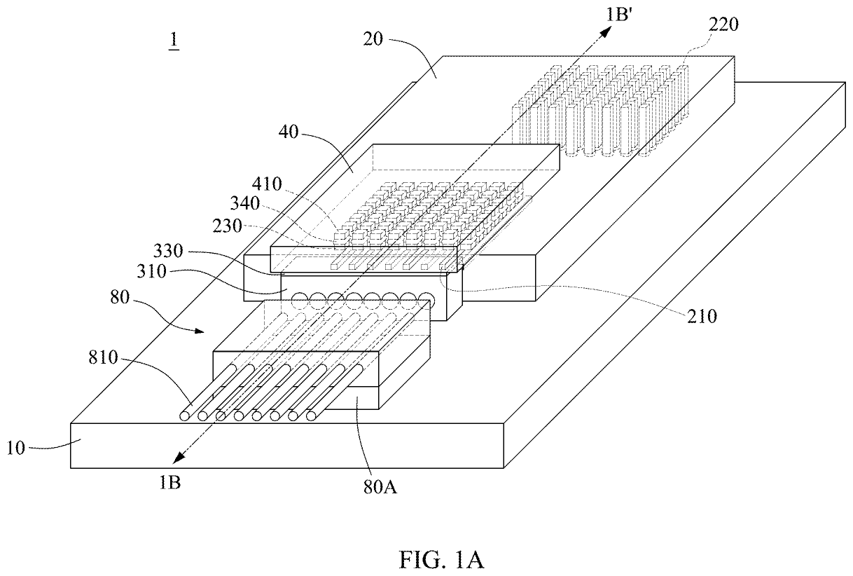

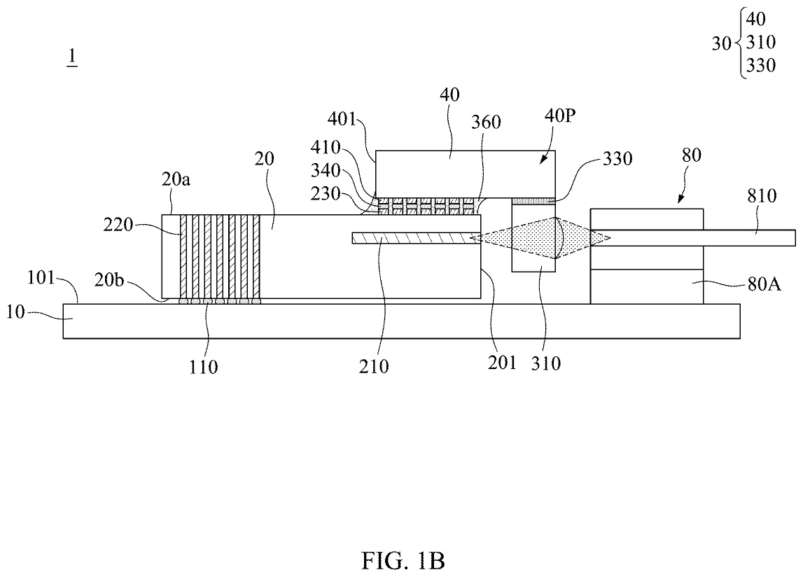

FIG. 1A is a perspective view of an electronic device 1 in accordance with some arrangements of the present disclosure. FIG. 1B is a cross-section of an electronic device 1 in accordance with some arrangements of the present disclosure. In some arrangements, FIG. 1B is a cross-section along a line 1B-1B′ in FIG. 1A. The electronic device 1 may include a carrier 10, an electronic component 20, a connecting element 30, and an optical component 80. The electronic device 1 may be referred to as a co-packaging optics (CPO).

The carrier 10 may support the electronic component 20. In some arrangements, the carrier 10 may include, for example, a printed circuit board, such as a paper-based copper foil laminate, a composite copper foil laminate, or a polymer-impregnated glass-fiber-based copper foil laminate. The carrier 10 may include an interconnection structure, such as a plurality of conductive traces and/or a plurality of conductive vias. In some arrangements, the carrier 10 includes a ceramic material or a metal plate. In some arrangements, the carrier 10 may include a substrate, such as an organic substrate or a leadframe. In some arrangements, the carrier 10 may include a two-layer substrate which includes a core layer and a conductive material and/or structure disposed on an upper surface and a bottom surface of the carrier 10. The conductive material and/or structure may include a plurality of conductive traces.

The electronic component 20 may be disposed over the carrier 10. In some arrangements, the electronic component 20 is electrically connected to the carrier 10. In some arrangements, the electronic component 20 is or includes a photonic component. The photonic component may include a photonic integrated circuit (PIC) or a photonic die. In some embodiments, the electronic component 20 (or the photonic component) may include a laser diode, a receiver, a waveguide, a photodetector, a photodiode, a semiconductor optical amplifier (SOA), a grating coupler, a fiber coupling structure, an optical modulator (e.g., Mach-Zehnder modulator or microring modulator), or a combination thereof. For example, the electronic component 20 may include a combination of photonic devices in a circuit and other active and passive optical devices on a single substrate to achieve a desired function. In some arrangements, the electronic component 20 (or the photonic component) is configured to provide a photoelectric conversion. In some arrangements, the electronic component 20 is configured to communicate optical signals (or modulated optical signals). For example, the electronic component 20 may be configured to transmit or receive optical signals.

In some arrangements, the electronic component 20 includes waveguides 210 (also referred to as “optical waveguides” or “optical channels”), conductive vias 220 (also referred to as “conductive pillars”), and conductive pads 230 (also referred to as “conductive pillars”, such as copper pillars). The electronic component 20 may further include one or more circuit layers that electrically connect the conductive vias 220 to the conductive pads 230 (or the electronic component 40). The electronic component 20 may have a surface 20a (also referred to as “a top surface” or “an active surface”), a surface 20b (also referred to as “a bottom surface” or “a back surface”) opposite to the surface 20a, and a surface 201 (also referred to as “a side surface”) extending between the surface 20a and the surface 20b. In some arrangements, the waveguide 210 is closer to the active surface (e.g., the surface 20a) than to the back surface (e.g., the surface 20b) of the electronic component 20. In some arrangements, the surface 201 (or the side surface) of the electronic component 20 is configured to optically couple with an optical element. In some arrangements, the waveguide 210 (or the optical channel) is exposed by the surface 201 of the electronic component 20 and configured to optically couple with an optical element. In some arrangements, the electronic component 20 is electrically connected to the carrier 10 through conductive vias 220 within the electronic component 20. In some arrangements, the electronic component 20 is electrically connected to the carrier 10 through the conductive vias 220 and connection elements 110. In some arrangements, the waveguides 210 may be formed of or include an optical waveguide material, e.g., a polymer material (e.g., a polymer waveguide), silicon nitride, silicon oxide, or other suitable materials. In some arrangements, a width of the waveguide 210 is from about 200 nm to about 500 nm. In some arrangements, a mode field diameter (MFD) of the waveguide 210 is from about 1 μm to about 3 μm. In some arrangements, the conductive vias 220 and the conductive pads 230 may independently be formed of or include an electrically conductive material such as a metal or a metal alloy. Examples may include gold (Au), silver (Ag), aluminum (Al), copper (Cu), or an alloy thereof. The conductive vias 220 may be or include through silicon vias (TSVs). In some arrangements, the connection elements 110 may be or include conductive bumps which may be or include Au, Ag, Cu, another metal, a solder alloy, or a combination of two or more thereof.

The connecting element 30 may be disposed at least partially over the electronic component 20. In some arrangements, the connecting element 30 is disposed over and connected to the surface 20a (or the top surface) of the electronic component 20. In some arrangements, the connecting element 30 includes an optical element 310, an adhesive layer 330, and an electronic component 40. In some arrangements, the connecting element 30 overhangs the electronic component 20 and includes an overhanging portion 40P. The electronic component 40 may include the overhanging portion 40P.

In some arrangements, the connecting element 30 is configured to solder to the electronic component 20 and define the optical element 310 at a specific position to conduct an optical transmission between the electronic component 20 and the optical element 310. In some arrangements, the optical element 310 is configured to optically couple to the side surface (e.g., the surface 201) of the electronic component 20. In some arrangements, the waveguide 210 (or the optical channel) is exposed by the surface 201 of the electronic component 20 and configured to optically couple to the optical element 310. In some arrangements, the waveguide 210 vertically overlaps the connecting element 30 (e.g., the electronic component 40) and horizontally overlaps the optical element 310. In some arrangements, the optical element 310 is connected to the overhanging portion 40P. In some arrangements, the optical element 310 is connected distantly to the electronic component 20 via a portion (e.g., the overhanging portion 40P) of the connecting element 30. In some arrangements, the optical element 310 is spaced apart from the carrier 10. In some arrangements, the optical element 310 may be or include a lens structure. The lens structure may include a body and one or more lenses connected to a surface of the body. The lens may be configured to convert focused lights to parallel light beams or convert parallel light beams to focused lights. The lens of the optical element 310 may be disposed on a surface of the body facing the optical component 80.

In some arrangements, the electronic component 40 is disposed above (or over) and electrically connected to the electronic component 20. In some arrangements, the electronic component 40 is electrically connected to the carrier 10 through the electronic component 20. In some arrangements, the electronic component 40 is connected to the top surface (e.g., the surface 20a) of the electronic component 20 through a soldering material. The soldering material may be or include solder bumps. In some arrangements, the connecting element 30 further includes a plurality of solder bumps 340 connecting the electronic component 40 to the electronic component 20. In some arrangements, the conductive pads 230 (or the conductive pillars, such as the copper pillars) of the electronic component 20 are electrically connected to conductive pads 410 (or conductive pillars, such as copper pillars) of the electronic component 40 through the solder bumps 340. In some arrangements, the electronic component 40 is connected to the optical element 310. In some arrangements, the electronic component 40 includes a portion (e.g., the overhanging portion 40P) overhanging the electronic component 20 and connected to the optical element 310. In some arrangements, the overhanging portion 40P protrudes beyond the surface 201 of the electronic component 20. In some arrangements, the optical element 310 is supported by or attached to the electronic component 40 and configured to optically couple with the electronic component 20. In some arrangements, the optical element 310 is adjacent to the surface 201 and connected to the overhanging portion 40P. In some arrangements, the waveguide 210 (or the optical channel) is exposed by the surface 201 of the electronic component 20 and directly under the electronic component 40, and the optical element 310 is configured to optically couple with the waveguide 210 (or the optical channel). In some arrangements, a portion of the connecting element 30 (or the electronic component 40) is disposed over the waveguides 210. In some arrangements, the optical element 310 is spaced apart from the surface 201 of the electronic component 20.

In some arrangements, the connecting element 30 may further include a logic circuit configured to communicate with the electronic component 20. The electronic component 40 may be or include the logic circuit. The logic circuit may be disposed over the electronic component 20. The logic circuit may further overhang the electronic component 20 and over the optical element 310. In some arrangements, the logic circuit (or the electronic component 40) is closer to the active surface (e.g., the surface 20a) of the electronic component 20 than to the back surface (e.g., the surface 20b) of the electronic component 20.

In some arrangements, the adhesive layer 330 connects the optical element 310 to the electronic component 40. In some arrangements, a coefficient of thermal expansion (CTE) of the adhesive layer 330 is less than a CTE of the solder bumps 340. In some arrangements, a melting point of the adhesive layer 330 is higher than a melting point of a soldering material. For example, the adhesive layer 330 may have a melting point higher than 300° C. In some arrangements, a melting point of the adhesive layer 330 is higher than a melting point of the solder bumps 340. In some arrangements, the optical element 310 is connected to a portion (e.g., the overhanging portion 40P) of the electronic component 40 through the adhesive layer 330. In some arrangements, the adhesive layer 330 is or includes an alloy material having a melting point higher than that of a soldering material (e.g., the solder bumps 340). In some arrangements, the adhesive layer 330 is made of or includes an UV glue (also referred to as “an UV gel” or “an UV adhesive”). The adhesive layer 330 may be made of or include an UV curable adhesive material. In some arrangements, the adhesive layer 330 includes AuSn.

According to some arrangements of the present disclosure, the melting point of the adhesive layer 330 is higher than the melting point of the solder bumps 340, and thus the adhesive layer 330 does not melt during the reflow process of the solder bumps 340 when bonding the connecting element 30 to the electronic component 20. Therefore, the shift in the relative position between the optical element 310 and the electronic component 40 can be prevented, the manufacturing process can be simplified, and the time and cost can be reduced.

In addition, according to some arrangements of the present disclosure, AuSn has a relatively low CTE, thus the shift in positions in vertical directions (e.g., in z-axis) between the optical element 310 and the electronic component 40 is relatively small, e.g., close to zero. Therefore, a relatively high the bonding accuracy can be provided with a variation in position shifts of equal to or lower than 1 μm.

In some arrangements, the connecting element 30 may further include a protective layer 360 encapsulating the solder bumps 340. In some arrangements, the protective layer 360 extends over a portion of a surface 401 (also referred to as “a side surface”) of the electronic component 40. In some arrangements, the protective layer 360 may protrude beyond the surface 201 of the electronic component 20. In some arrangements, the surface 201 of the electronic component 20 is configured to optically couple with the optical element 310 and spaced apart from the protective layer 360. The protective layer 360 may be or include an encapsulant, an underfill, or the like. In some arrangements, the protective layer 360 includes an epoxy resin, a molding compound (e.g., an epoxy molding compound or other molding compound), polyimide, a phenolic compound or material, a material including a silicone dispersed therein, or a combination thereof. The protective layer 360 may further include fillers (silicon-based fillers).

The optical component 80 (also referred to as “optical element”) may be disposed over the carrier 10. In some arrangements, the optical component 80 is adhered to the carrier 10 through an adhesive layer 80A. In some arrangements, the optical component 80 (or the optical element) is configured to optically couple with the waveguides 210 (or the optical channels). In some arrangements, the optical component 80 includes a plurality of fibers 810 (or optical fibers). In some arrangements, the optical component 80 is optically coupled to the electronic component 20 through the optical element 310. In some arrangements, the fibers 810 are optically coupled to the waveguides 210 through the optical element 310. The optical component 80 may be or include a fiber array unit (FAU). In some arrangements, a width of the fiber 810 is about 125 μm. In some arrangements, a mode field diameter (MFD) of the fiber 810 is about 10.4 μm. In some arrangements, the adhesive layer 80A is made of or includes an UV glue (also referred to as “an UV gel” or “an UV adhesive”). The adhesive layer 80A may be made of or include an UV curable adhesive material. In some arrangements, the adhesive layer 80A may be or include a die attach film (DAF).

In some arrangements, the optical element 310 is self-aligned with the waveguide 210 (or the optical channel) and defined at a specific position to be configured to direct an optical signal between the waveguide 210 and the optical component 80 (or the optical element). In some arrangements, the connecting element 30 (e.g., the electronic component 40) connects the electronic component 20 to the optical element 310. The connecting element 30 (or the electronic component 40) may include a first connection (e.g., the conductive pads 410), and the electronic component 20 may include a second connection (e.g., the conductive pads 230) self-aligned with the first connection (e.g., the conductive pads 410) to self-align the optical element 310 with the waveguide 210 (or the optical channel). The first connection (or the conductive pads 410) may be connected to the second connection (or the conductive pads 230) through a soldering material or a reflowable material (e.g., the solder bumps 340). In some arrangements, the protective layer 360 further encapsulates the soldering material or the reflowable material and connects the electronic component 20 to the connecting element 30. In some arrangements, the connecting element 30 (e.g., the electronic component 40) includes a logic circuit.

In some cases, an optical element is actively aligned with a photonic component by monitoring an optical signal received by the photonic component that is transmitted from a light source outside of the optical element. The light source has to be turned on when moving the optical element until an optimum optical signal is monitored by the photonic component to complete the active alignment process. The light source occupies an extra volume, and a relatively complicated setup is required to move the optical element with the light source being turned on or powered up (connected to a power supply), thus the active alignment process cause a significant reduction of the unit per hour (UPH) of the manufacturing process of the electronic device.

According to some arrangements of the present disclosure, the connecting element 30 is configured to solder to the electronic component 20 and define the optical element 310 at a specific position to conduct an optical transmission between the electronic component 20 and the optical element 310, such that the optical element 310 is passively aligned or self-aligned with the electronic component 20. Therefore, the time and the cost for aligning the optical element 310 with the electronic component 20 can be reduced, and thus the UPH of the manufacturing process of the electronic device 1 can be increased.

Moreover, according to some arrangements of the present disclosure, the connecting element 30 is bonded to the electronic component 20 through the solder bumps 340 by passive alignment or self-alignment. Because the solder bumps 340 have surface tension during the reflow process, the optical element 310 attached to the connecting element 30 on the solder bumps 340 are able to self-align and allow the optical element 310 to reach the specific position for conducting the optical transmission between the waveguides 210 and the optical element 310. Therefore, in addition to that the solder bumps 340 can provide electrical connection between the electronic component 20 and the electronic component 40, the passive alignment between the optical element 310 and the waveguides 210 of the electronic component 20 can be achieved by self-alignment of the soldering materials of the solder bumps 340. Therefore, the UPH of the manufacturing process of the electronic device 1 can be increased.

Furthermore, according to some arrangements of the present disclosure, the solder bumps 340 are configured to electrically connect to high-density circuits (e.g., the conductive pads 230) of the electronic component 20 and thus have a relatively small pitch (e.g., with a fine line width/space (L/S)). Therefore, the alignment accuracy and precision of the passive alignment between the optical element 310 and the waveguides 210 by self-alignment of the solder bumps 340 resulted from the reflow operation on the solder bumps 340 can be increased as well. Accordingly, the small pitch between the solder bumps 340 may preliminarily define the positions of the solder bumps 340 with a relatively high accuracy and precision before the reflow operation, and then the reflow operation of the solder bumps 340 allows the optical element 310 to self-align with the waveguide 210 and thereby be defined at a specific position (or a predetermined or a pre-designed specific position) to be configured to direct an optical signal between the waveguide 210 and the fiber 810 of the optical component 80. For example, the relatively small MFD of the waveguide 210 can be entirely overlapped with the MFD of the fiber 810, and thus the optically coupling efficiency can be increased.

In addition, according to some arrangements of the present disclosure, the electronic component 40 is used as a portion of the connecting element 30, such that additional space over the electronic component 20 can be provided for disposing additional components. Therefore, the overall size of the electronic device 1 can be reduced.

Moreover, according to some arrangements of the present disclosure, the electronic component 20 is electrically connected to the carrier 10 through conductive vias 220 within the electronic component 20. The transmission path provided by the conductive vias 220 within the electronic component 20 are relatively short compared to other interconnection structure outside of the electronic component 20, e.g., bonding wires. Therefore, the transmission loss, particularly for high-frequency transmission, can be further reduced.

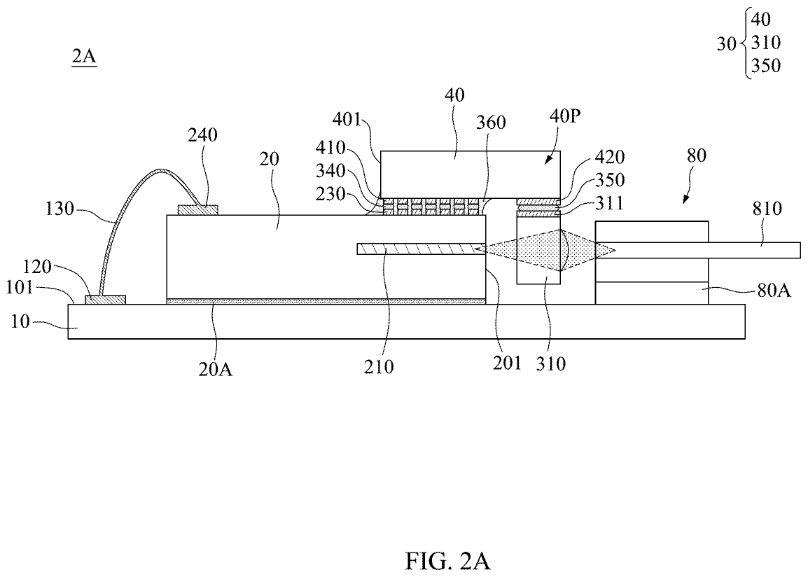

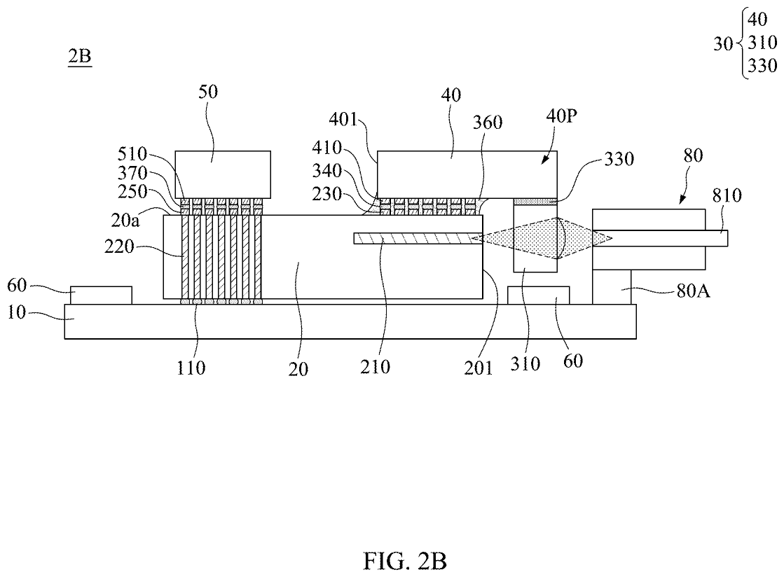

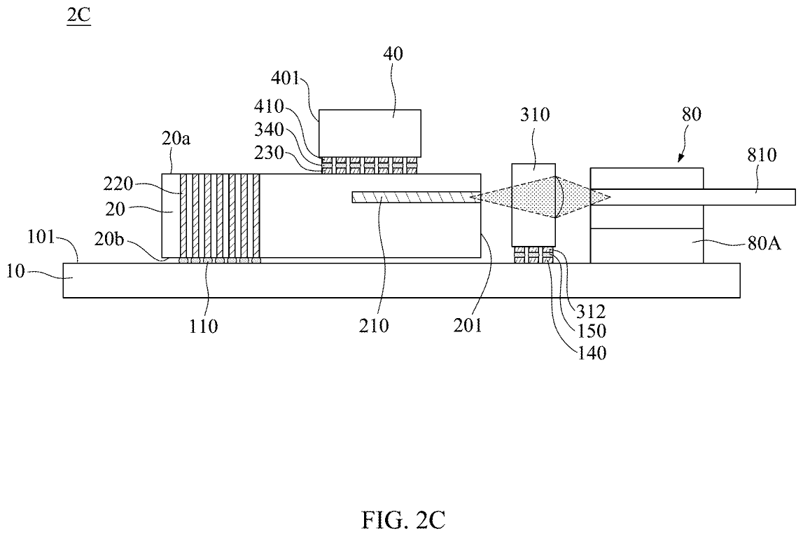

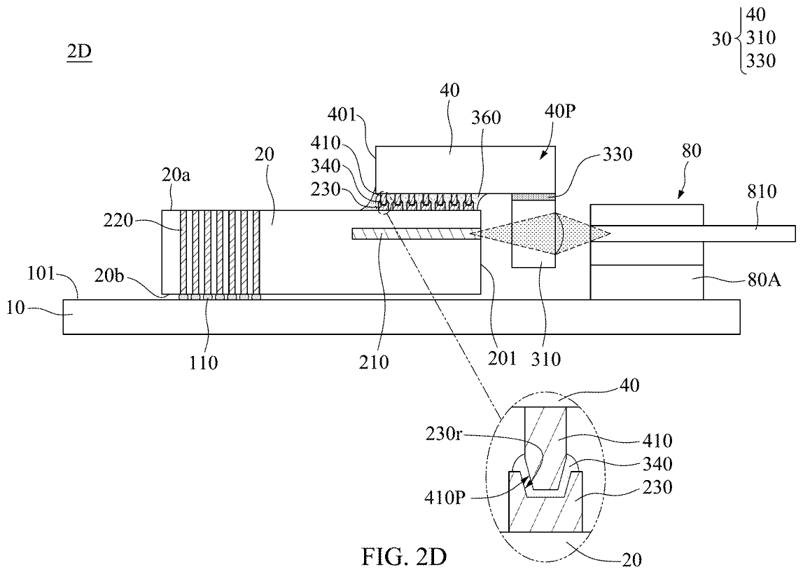

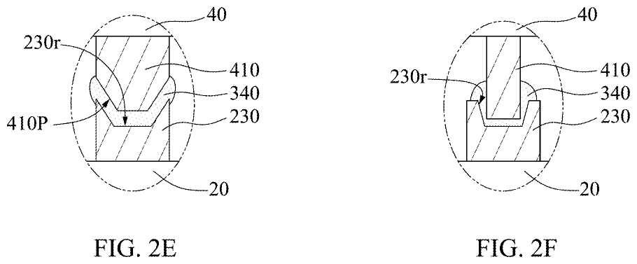

FIG. 2A is a cross-section of an electronic device 2A in accordance with some arrangements of the present disclosure. The electronic device 2A is similar to the electronic device 1 in FIG. 1A and FIG. 1B, and the differences therebetween are described as follows.

In some arrangements, the optical element 310 is connected to the logic circuit (e.g., the electronic component 40) through a soldering material. The soldering material may be or include a solder bump 350. In some arrangements, a pad 420 of the electronic component 40 is connected to a pad 311 of the optical element 310 through the solder bump 350. The pads 311 and 420 may be conductive pads, dummy pads, or dummy conductive pads. Dummy pads or dummy conductive pads may be referred to pads or conductive pads that do not provide electrical connection functions. In some arrangements, a melting point of the solder bump 350 is higher than a melting point of the solder bumps 340. In some arrangements, the connecting element 30 includes the optical element 310, the electronic component 40, and the solder bump 350.

In some arrangements, the electronic component 20 is adhered to the carrier 10 through an adhesive layer 20A. In some arrangements, the electronic component 20 is electrically connected to the carrier 10 through a conductive wire 130. In some arrangements, a conductive pad 240 of the electronic component 20 is electrically connected to a conductive pad (e.g., the connection element 120) of the carrier 10 through the conductive wire 130. The adhesive layer 20A may be or include a DAF. The conductive wire 130 may be formed of or include an electrically conductive material such as a metal or a metal alloy. Examples may include Au, Ag, Al, Cu, or an alloy thereof.

According to some arrangements of the present disclosure, the connecting element 30 is bonded to the optical element 310 through the solder bump 350. Because the solder bump 350 has surface tension during the reflow process, the optical element 310 on the solder bump 350 is able to self-align and further allow the optical element 310 to reach the specific position for conducting the optical transmission between the waveguides 210 and the optical element 310. Therefore, in addition to the self-alignment provided by the solder bumps 340, the solder bump 350 can further self-align the optical element 310, and thus the passive alignment between the optical element 310 and the waveguides 210 of the electronic component 20 can be achieved by self-alignments of the soldering materials of the solder bumps 340 and 350. Therefore, the UPH of the manufacturing process of the electronic device 2A can be increased, and the alignment accuracy and precision of the passive alignment between the optical element 310 and the waveguides 210 by self-alignment of the solder bumps 340 and 350 can be further increased.

FIG. 2B is a cross-section of an electronic device 2B in accordance with some arrangements of the present disclosure. The electronic device 2B is similar to the electronic device 1 in FIG. 1A and FIG. 1B, and the differences therebetween are described as follows.

In some arrangements, the electronic device 2B further includes electronic components 50 and 60.

In some arrangements, the electronic component 50 is disposed over and electrically connected to the electronic component 20. In some arrangements, the electronic component 50 is electrically connected to the electronic component 40 through the electronic component 20. In some arrangements, the electronic component 50 is electrically connected to the carrier 10 through the conductive vias 220. In some arrangements, conductive pads 510 of the electronic component 50 are electrically connected to conductive pads 250 of the electronic component 20 through solder bumps 370. In some arrangements, the electronic component 50 is or includes a processing component. In some arrangements, the electronic component 50 includes an ASIC, an FPGA, a GPU, or the like, or a combination thereof. The electronic component 50 may electrically communicate with the electronic component 40 through a circuit layer or an RDL (not shown) within the electronic component 20.

In some arrangements, the electronic components 60 may be or include passive components. In some arrangements, the electronic components 60 are disposed over a top surface (e.g., a surface 101) of the carrier 10. In some arrangements, at least one of the electronic components 60 is disposed in a gap between the carrier 10 and the optical element 310. In some arrangements, the optical element 310 is over and spaced apart from the top surface (e.g., the surface 101) of the carrier 10, and one of the electronic components 60 is disposed between the optical element 310 and the top surface of the carrier 10. In some arrangements, the electronic components 60 are electrically connected to the carrier 10. In some arrangements, the electronic component 60 may be or include a passive electronic component, such as a capacitor, a resistor, an inductor, a trans-impedance amplifier (TIA), or a combination thereof.

FIG. 2C is a cross-section of an electronic device 2C in accordance with some arrangements of the present disclosure. The electronic device 2C is similar to the electronic device 1 in FIG. 1A and FIG. 1B, and the differences therebetween are described as follows.

In some arrangements, the optical element 310 is connected to the carrier 10 through a soldering material. The soldering material may be or include one or more solder bumps 150. In some arrangements, pads 140 of the carrier 10 are connected to pads 312 of the optical element 310 through the solder bumps 150. The pads 312 and 140 may be conductive pads, dummy pads, or dummy conductive pads. Dummy pads or dummy conductive pads may be referred to pads or conductive pads that do not provide electrical connection functions. In some arrangements, the carrier 10 may serve as a connecting element that connects the electronic component 20 to the optical element 310, and a soldering material (e.g., the solder bumps 150) connects the optical element 310 to the connecting element (e.g., the carrier 10). In some arrangements, the carrier 10 supports the optical component 80. In some arrangements, the carrier 10 is or includes an interposer (e.g., a silicon interposer).

According to some arrangements of the present disclosure, the solder bumps 150 are configured to electrically connect to the pads 140 of the carrier 10 having a relatively high density and thus having a relatively small pitch (e.g., with a fine line width/space (L/S)). Therefore, the alignment accuracy and precision of the passive alignment between the optical element 310 and the waveguides 210 by self-alignment of the solder bumps 150 resulted from the reflow operation on the solder bumps 150 can be increased as well. Accordingly, the small pitch between the solder bumps 150 may preliminarily define the positions of the solder bumps 150 with a relatively high accuracy and precision before the reflow operation, and then the reflow operation of the solder bumps 150 allows the optical element 310 to self-align with the waveguide 210 and thereby be defined at a specific position (or a predetermined or a pre-designed specific position) to be configured to direct an optical signal between the waveguide 210 and the fiber 810 of the optical component 80. For example, the relatively small MFD of the waveguide 210 can be entirely overlapped with the MFD of the fiber 810, and thus the optically coupling efficiency can be increased.

FIG. 2D is a cross-section of an electronic device 2D in accordance with some arrangements of the present disclosure. The electronic device 2D is similar to the electronic device 1 in FIG. 1A and FIG. 1B, and the differences therebetween are described as follows.

In some arrangements, the conductive pad 230 (or the second connection of the electronic component 20) defines a recess 230r, and a portion of the conductive pad 410 (or the first connection of the connecting element 30) extends into the recess 230r to connect to the conductive pad 230. In some arrangements, a width of the conductive pad 410 is less than a width of the conductive pad 230. In some arrangements, the conductive pad 410 includes a tapered portion 410P tapering toward and at least partially disposed in the recess 230r. In some arrangements, an outer cross-sectional profile of the tapered portion 410P is substantially conformal with an inner cross-sectional profile of the recess 230r. In some arrangements, the conductive pad 230 is spaced apart from the conductive pad 410 by the solder bump 340. In some arrangements, the solder bump 340 is disposed in the recess 230r and encapsulates the tapered portion 410P. In some arrangements, the solder bump 340 self-aligns the conductive pad 230 with the conductive pad 410 to connect the conductive pad 230 to the conductive pad 410.

According to some arrangements of the present disclosure, the solder bumps 340 are configured to electrically connect to high-density circuits (e.g., the conductive pads 230) of the electronic component 20 and thus have a relatively small pitch (e.g., with a fine line width/space (L/S)). Therefore, the alignment accuracy and precision of the passive alignment between the optical element 310 and the waveguides 210 by self-alignment of the solder bumps 340 resulted from the reflow operation on the solder bumps 340 can be increased as well. In addition, the recesses 230r can further direct or guide the conductive pads 410 to self-align with the conductive pads 230. Accordingly, the small pitch between the conductive pads 230 may preliminarily define the positions of the conductive pads 410 with a relatively high alignment accuracy and precision before the reflow operation, and then the reflow operation of the solder bumps 340 allows the conductive pads 410 to further self-align with the conductive pads 230, such that the optical element 310 is self-aligned with the waveguide 210 and thereby defined at a specific position (or a predetermined or a pre-designed specific position) to be configured to direct an optical signal between the waveguide 210 and the fiber 810 of the optical component 80. For example, the relatively small MFD of the waveguide 210 can be entirely overlapped with the MFD of the fiber 810, and thus the optically coupling efficiency can be increased.

FIG. 2E is a cross-section of a portion of an electronic device in accordance with some arrangements of the present disclosure. The portion of the electronic device illustrated in FIG. 2E is similar to a portion of the electronic device 1 in FIG. 1A and FIG. 1B, and the differences therebetween are described as follows.

In some arrangements, a width of the conductive pad 410 is substantially the same as or greater than a width of the conductive pad 230. In some arrangements, the solder bump 340 protrudes beyond lateral surfaces of the conductive pads 230 and 410. The solder bump 340 may partially cover the lateral surface of the conductive pad 230 and/or the lateral surface of the conductive pad 410.

FIG. 2F is a cross-section of a portion of an electronic device in accordance with some arrangements of the present disclosure. The portion of the electronic device illustrated in FIG. 2F is similar to a portion of the electronic device 1 in FIG. 1A and FIG. 1B, and the differences therebetween are described as follows.

In some arrangements, a width of the conductive pad 410 is less than a width of the conductive pad 230. In some arrangements, the conductive pad 410 has a substantially uniform width. In some arrangements, the solder bump 340 is filled in the recess 230r and partially covers the lateral surface of the conductive pad 410.

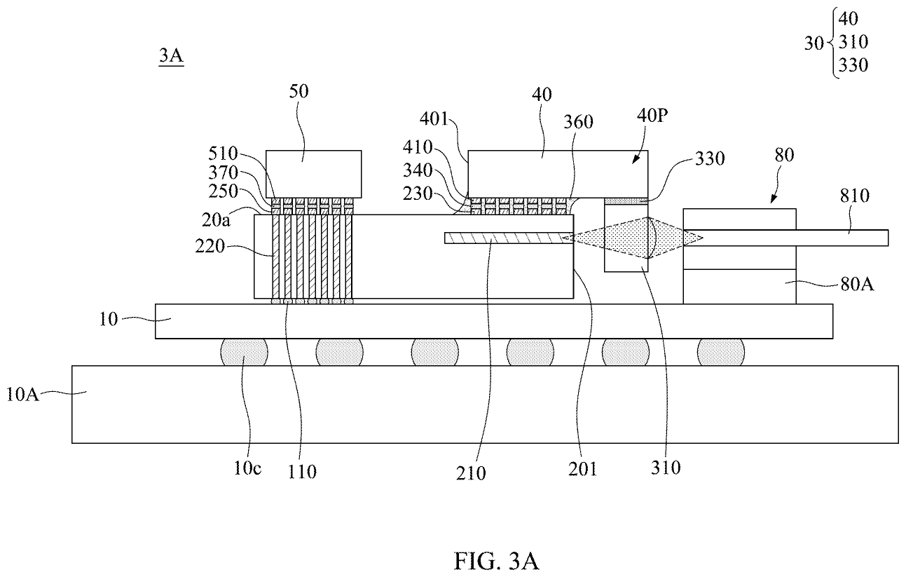

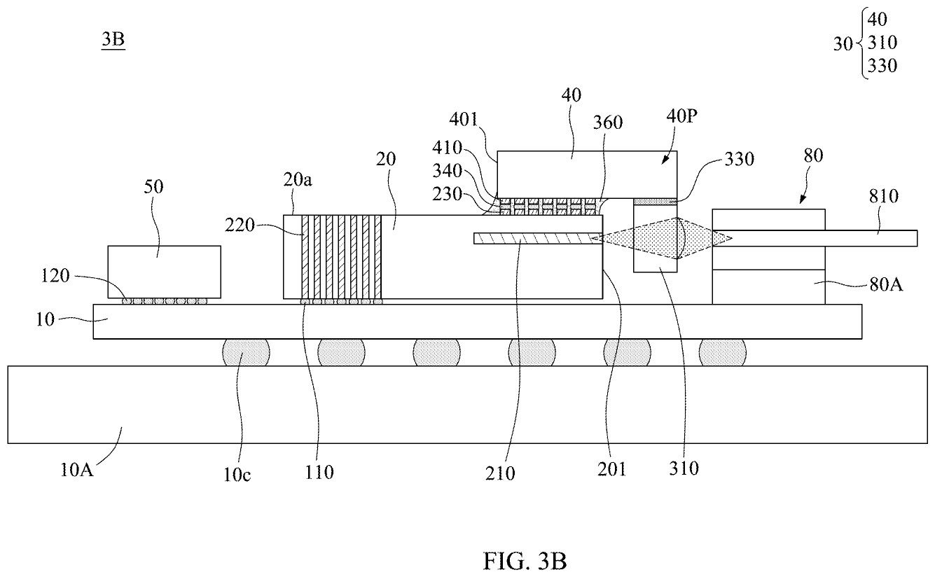

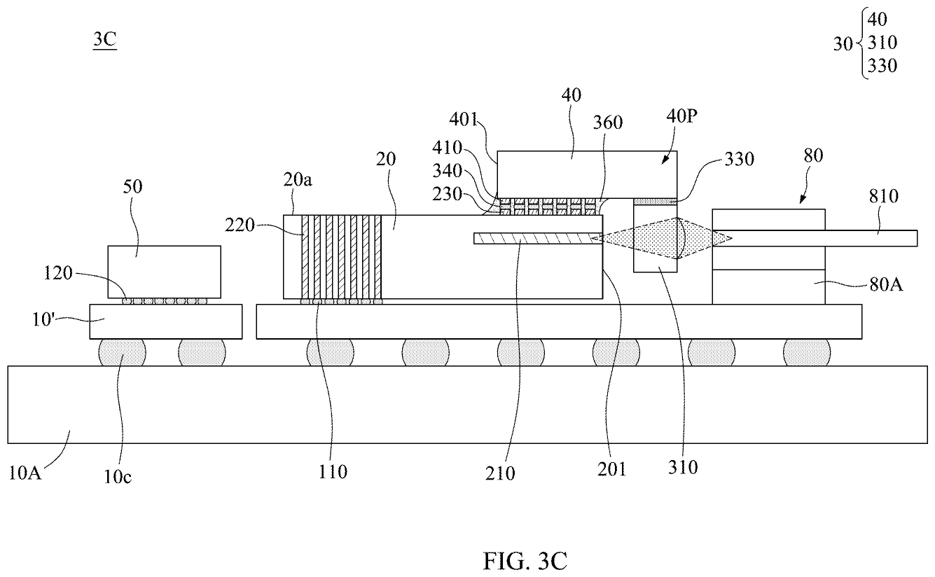

FIG. 3A is a cross-section of an electronic device 3A in accordance with some arrangements of the present disclosure. The electronic device 3A is similar to the electronic device 2B in FIG. 2B, and the differences therebetween are described as follows.

In some arrangements, the electronic device 3A further includes a carrier 10A and a plurality of electrical contacts 10c. In some arrangements, the carrier 10A may include, for example, a printed circuit board, such as a paper-based copper foil laminate, a composite copper foil laminate, or a polymer-impregnated glass-fiber-based copper foil laminate. The carrier 10A may include an interconnection structure, such as a plurality of conductive traces and/or a plurality of conductive vias. In some arrangements, the carrier 10A includes a ceramic material or a metal plate. In some arrangements, the carrier 10A may include a substrate, such as an organic substrate or a leadframe. In some arrangements, the carrier 10A may include a two-layer substrate which includes a core layer and a conductive material and/or structure disposed on an upper surface and a bottom surface of the carrier 10A. The conductive material and/or structure may include a plurality of conductive traces.

In some arrangements, the structure illustrated in FIG. 2B is disposed over the carrier 10A. In some arrangements, the carrier 10A supports and electrically connects to the electronic component 20 through the electrical contacts 10c. In some arrangements, a pitch of the solder bumps 340 is less than a pitch of the electrical contacts 10c. The electrical contacts 10c may be or include solder balls. In some embodiments, the electrical contacts 10c include controlled collapse chip connection (C4) bumps, a ball grid array (BGA), or a land grid array (LGA).

FIG. 3B is a cross-section of an electronic device 3B in accordance with some arrangements of the present disclosure. The electronic device 3B is similar to the electronic device 1 in FIG. 1A, and FIG. 1B, and the differences therebetween are described as follows.

In some arrangements, the electronic component 50 is disposed over and electrically connected to the carrier 10. In some arrangements, the electronic component 50 is electrically connected to the carrier 10 through connection elements 120. In some arrangements, the electronic component 50 is electrically connected to the carrier 10A through the carrier 10. In some arrangements, the connection elements 120 may be or include conductive bumps which may be or include Au, Ag, Cu, another metal, a solder alloy, or a combination of two or more thereof.

FIG. 3C is a cross-section of an electronic device 3C in accordance with some arrangements of the present disclosure. The electronic device 3C is similar to the electronic device 1 in FIG. 1A, and FIG. 1B, and the differences therebetween are described as follows.

In some arrangements, the electronic device 3C further includes a carrier 10′. In some arrangements, the carrier 10′ is disposed over and electrically connected to the carrier 10 through the electrical contacts 10c. The carrier 10′ may be similar to the carrier 10, and the description is omitted hereinafter.

In some arrangements, the electronic component 50 is disposed over and electrically connected to the carrier 10′. In some arrangements, the electronic component 50 is electrically connected to the carrier 10′ through the connection elements 120. In some arrangements, the electronic component 50 is electrically connected to the carrier 10A through the carrier 10′.

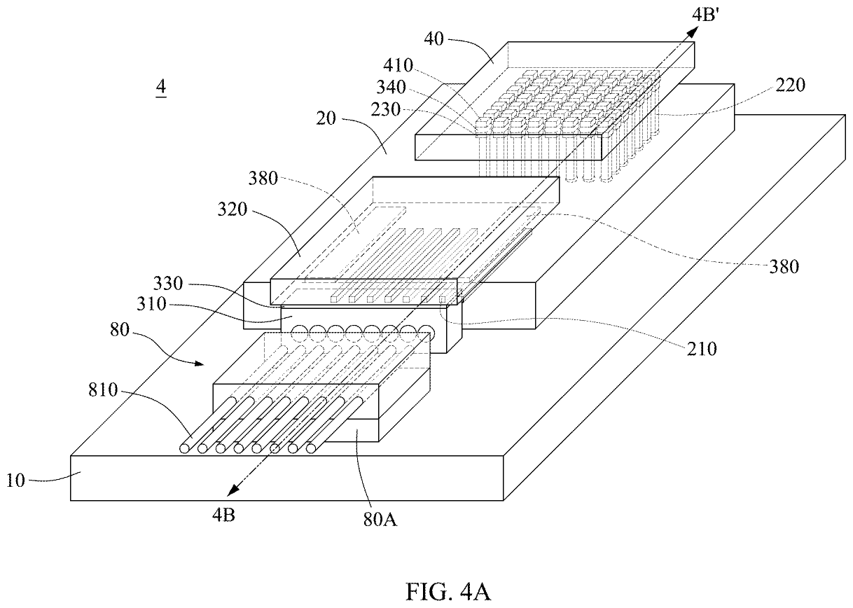

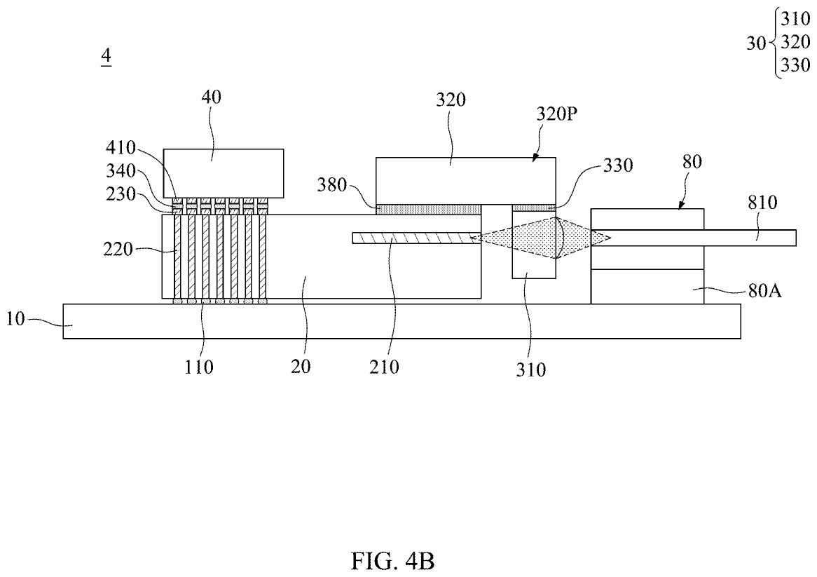

FIG. 4A is a perspective view of an electronic device 4 in accordance with some arrangements of the present disclosure. FIG. 4B is a cross-section of an electronic device 4 in accordance with some arrangements of the present disclosure. In some arrangements, FIG. 4B is a cross-section along a line 4B-4B′ in FIG. 4A. The electronic device 4 is similar to the electronic device 1 in FIG. 1A, and FIG. 1B, and the differences therebetween are described as follows.

In some arrangements, the connecting element 30 includes the optical element 310, the adhesive layer 330, and a supporting element 320. In some arrangements, the connecting element 30 overhangs the electronic component 20 and includes an overhanging portion 320P. In some arrangements, the electronic component 40 is disposed separated from or spaced apart from the connecting element 30. In some arrangements, the electronic component 40 is disposed over and electrically connected to the top surface (e.g., the surface 20a) of the electronic component 20. The supporting element 320 may be or include an insulating supporter. In some arrangements, the supporting element 320 is or includes a glass layer, a silicon layer, or the like.

In some arrangements, the supporting element 320 is connected to the top surface (e.g., the surface 20a) of the electronic component 20 and the optical element 310. In some arrangements, the connecting element 30 further includes one or more adhesive layers 380. In some arrangements, the supporting element 320 is connected to the surface 20a of the electronic component 20 through the adhesive layers 380. In some arrangements, the adhesive layers 380 adhere the supporting element 320 to the surface 20a of the electronic component 20. In some arrangements, the adhesive layer 380 includes a curable adhesive. In some arrangements, the adhesive layer 380 is made of or includes an UV glue (also referred to as “an UV gel” or “an UV adhesive”). The adhesive layer 380 may be made of or include an UV curable adhesive material. In some arrangements, the adhesive layer 380 includes AuSn.

In some arrangements, the supporting element 320 includes a portion (e.g., the overhanging portion 320P) overhanging the electronic component 20 and connected to the optical element 310. In some arrangements, the optical element 310 is supported by or attached to the supporting element 320 and configured to optically couple with the electronic component 20. In some arrangements, the optical element 310 is connected to the overhanging portion 320P. In some arrangements, the optical element 310 is connected distantly to the electronic component 20 via a portion (e.g., the overhanging portion 320P) of the connecting element 30.

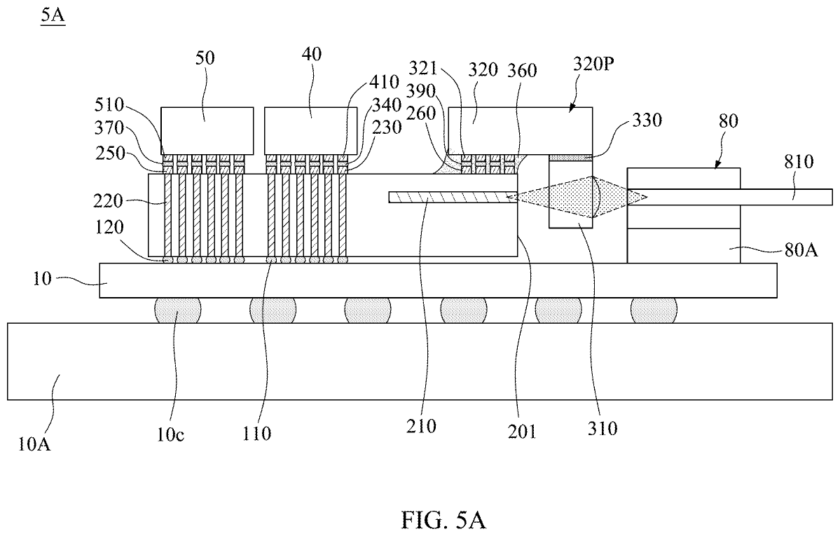

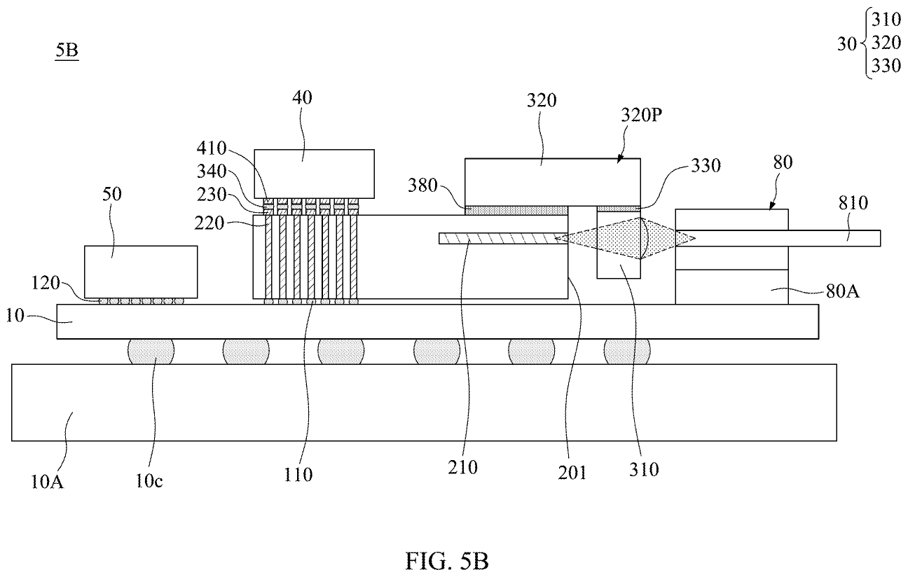

FIG. 5A is a cross-section of an electronic device 5A in accordance with some arrangements of the present disclosure. The electronic device 5A is similar to the electronic device 4 in FIG. 4A, and FIG. 4B, and the differences therebetween are described as follows.

In some arrangements, the supporting element 320 is configured to solder to the electronic component 20 and define the optical element 310 at a specific position to conduct an optical transmission between the electronic component 20 and the optical element 310. In some arrangements, the supporting element 320 is soldered to the electronic component 20 and adhered to the optical element 310 through the adhesive layer 330.

In some arrangements, the connecting element 30 further includes a plurality of solder bumps 390 connecting the supporting element 320 to the electronic component 20. In some arrangements, pads 260 of the electronic component 20 are connected to pads 321 of the supporting element 320 through the solder bumps 390. The pads 321 and 260 may be conductive pads, dummy pads, or dummy conductive pads. Dummy pads or dummy conductive pads may be referred to pads or conductive pads that do not provide electrical connection functions. In some arrangements, the supporting element 320 is connected to the optical element 310. In some arrangements, the supporting element 320 includes a portion (e.g., the overhanging portion 320P) overhanging the electronic component 20 and connected to the optical element 310. In some arrangements, the optical element 310 is supported by or attached to the supporting element 320 and configured to optically couple with the electronic component 20. In some arrangements, the waveguide 210 (or the optical channel) is exposed by the surface 201 of the electronic component 20 and directly under the supporting element 320, and the optical element 310 is configured to optically couple with the waveguide 210 (or the optical channel).

In some arrangements, the electronic device 5A further includes the electronic component 50. In some arrangements, the electronic component 50 is disposed over and electrically connected to the electronic component 20. In some arrangements, the electronic component 50 is electrically connected to the carrier 10 through the conductive vias 220. In some arrangements, conductive pads 510 of the electronic component 50 are electrically connected to conductive pads 250 of the electronic component 20 through solder bumps 370. In some arrangements, the electronic component 50 is or includes a processing component. In some arrangements, the electronic component 50 includes an ASIC, an FPGA, a GPU, or the like, or a combination thereof. The electronic component 50 may electrically communicate with the electronic component 40 through a circuit layer or an RDL (not shown) within the electronic component 20.

FIG. 5B is a cross-section of an electronic device 5B in accordance with some arrangements of the present disclosure. The electronic device 5B is similar to the electronic device 4 in FIG. 4A, and FIG. 4B, and the differences therebetween are described as follows.

In some arrangements, the electronic component 50 is disposed over and electrically connected to the carrier 10. In some arrangements, the electronic component 50 is electrically connected to the carrier 10 through connection elements 120. In some arrangements, the electronic component 50 is electrically connected to the carrier 10A through the carrier 10. In some arrangements, the connection elements 120 may be or include conductive bumps which may be or include Au, Ag, Cu, another metal, a solder alloy, or a combination of two or more thereof.

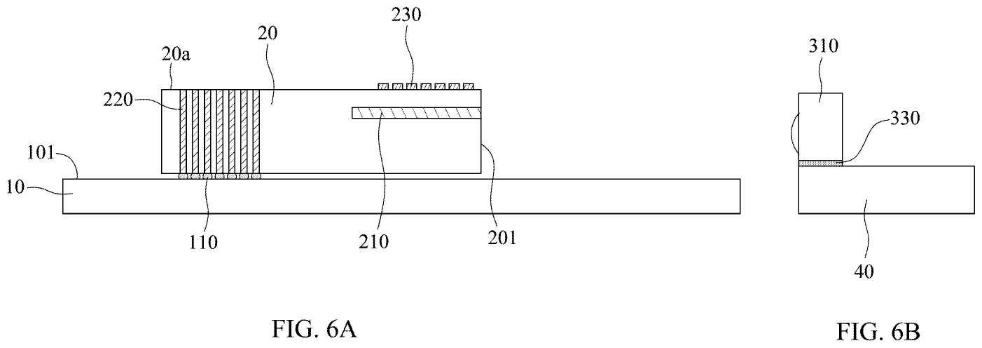

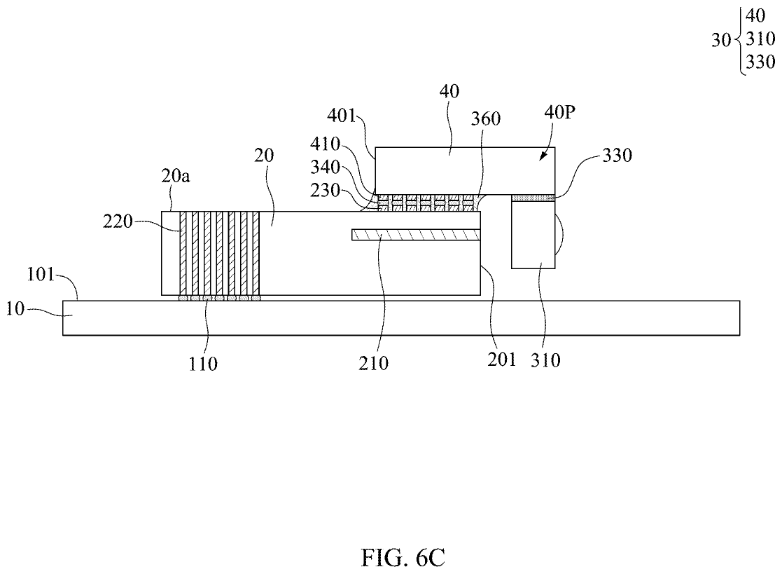

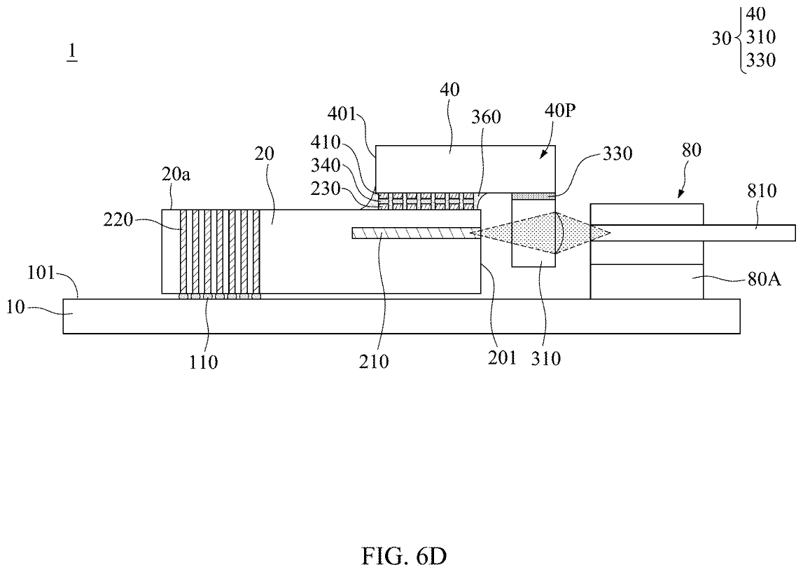

FIG. 6A, FIG. 6B, FIG. 6C, and FIG. 6D illustrate various stages of an exemplary method for manufacturing an electronic device 1 in accordance with some embodiments of the present disclosure.

Referring to FIG. 6A, a carrier 10 may be provided, and an electronic component 20 may be disposed over and electrically connected to the carrier 10. In some arrangements, the electronic component 20 includes waveguides 210, conductive vias 220, and conductive pads 230. In some arrangements, the electronic component 20 is bonded or joint to the surface 101 of the carrier 10 through connection elements 110. In some arrangements, a wafer-level carrier may be provided, a plurality of electronic components 20 may be disposed over the electrically connected to the wafer-level carrier, and then a singulation operation may be performed on the wafer-level carrier to form a plurality of the structures illustrated in FIG. 6A.

Referring to FIG. 6B, an electronic component 40 may be provided, and an optical element 310 may be connected to the electronic component 40 through an adhesive layer 330.

Referring to FIG. 6C, the electronic component 40 may be bonded of joint to the electronic component 20 by way of solder joint technique. In some arrangements, conductive pads 410 of the electronic component 40 are bonded to the conductive pads 230 of the electronic component 20 through solder bumps 340 followed by encapsulating the solder bumps 340 by a protective layer 360. In some arrangements, the optical element 310 is optically passively aligned with the waveguides 210. In some arrangements, the connecting element 30 is configured to solder to the electronic component 20 and define the optical element 310 at a specific position to conduct an optical transmission between the electronic component 20 and the optical element 310.

Referring to FIG. 6D, an optical component 80 including fibers 810 may be disposed over the carrier 10 to optically couple to the waveguides 210 of the electronic component 20. In some arrangements, an active alignment operation is performed to align the fibers 810 of the optical component 80 with the waveguides 210, and then the optical component 80 is attached to the carrier 10 through an adhesive layer 80A at a position determined by the active alignment operation. As such, the electronic device 1 illustrated in FIG. 1A and FIG. 1B may be formed.

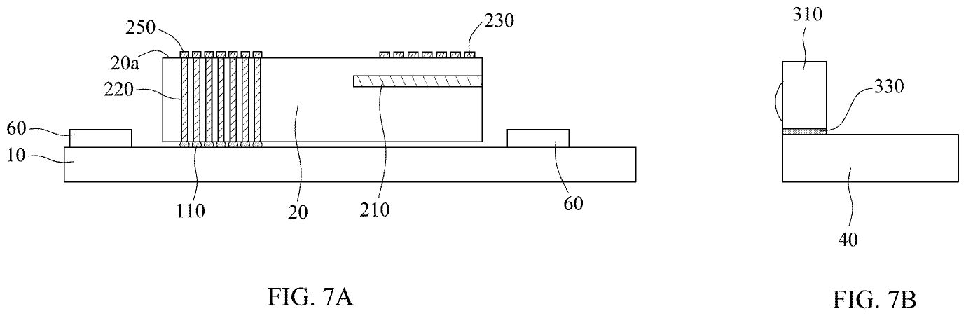

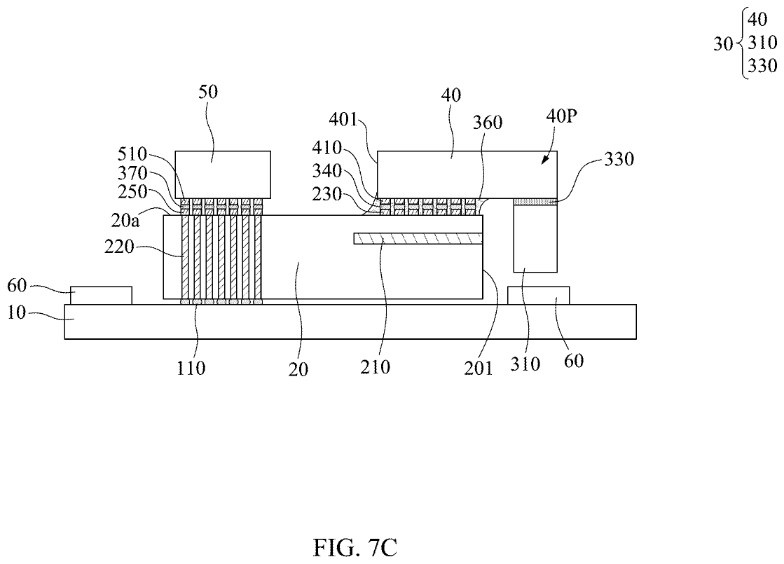

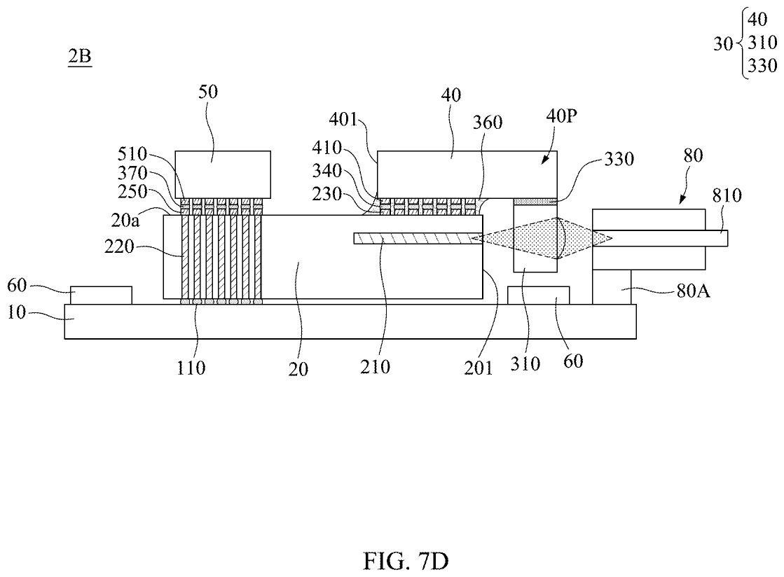

FIG. 7A, FIG. 7B, FIG. 7C, and FIG. 7D illustrate various stages of an exemplary method for manufacturing an electronic device 2B in accordance with some embodiments of the present disclosure.

Referring to FIG. 7A, a carrier 10 may be provided, and electronic components 20 and 60 may be disposed over and electrically connected to the carrier 10. In some arrangements, the electronic component 20 includes waveguides 210, conductive vias 220, and conductive pads 230 and 250. In some arrangements, the electronic component 20 is bonded or joint to the surface 101 of the carrier 10 through connection elements 110.

Referring to FIG. 7B, an electronic component 40 may be provided, and an optical element 310 may be connected to the electronic component 40 through an adhesive layer 330.

Referring to FIG. 7C, operations similar to those illustrated in FIG. 6C may be performed to bond of joint the electronic component 40 to the electronic component 20, and an electronic component 50 may be bonded of joint to the electronic component 20 by way of solder joint technique. In some arrangements, conductive pads 510 of the electronic component 50 are bonded to the conductive pads 250 of the electronic component 20 through solder bumps 370

Referring to FIG. 7D, an optical component 80 including fibers 810 may be disposed over the carrier 10 to optically couple to the waveguides 210 of the electronic component 20. In some arrangements, an active alignment operation is performed to align the fibers 810 of the optical component 80 with the waveguides 210, and then the optical component 80 is attached to the carrier 10 through an adhesive layer 80A at a position determined by the active alignment operation. As such, the electronic device 2B illustrated in FIG. 2B may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a photonic component comprising an optical channel;
a first optical element configured to optically couple with the optical channel; and
a second optical element self-aligned with the optical channel and defined at a specific position to be configured to direct an optical signal between the optical channel and the first optical element.

2. The electronic device as claimed in claim 1, further comprising a connecting element connecting the photonic component to the second optical element, wherein the connecting element comprises a first connection, and the photonic component comprises a second connection self-aligned with the first connection to self-align the second optical element with the optical channel.

3. The electronic device as claimed in claim 2, further comprising a soldering material connecting the first connection to the second connection.

4. The electronic device as claimed in claim 3, further comprising a protective layer encapsulating the soldering material and connecting the photonic component to the connecting element.

5. The electronic device as claimed in claim 2, wherein the connecting element comprises a logic circuit.

6. The electronic device as claimed in claim 5, wherein the logic circuit is closer to an active surface of the photonic component than to a back surface opposite to the active surface of the photonic component.

7. The electronic device as claimed in claim 2, wherein the second connection defines a recess, and a portion of the first connection extends into the recess to connect to the second connection.

8. The electronic device as claimed in claim 1, further comprising:
a connecting element connecting the photonic component to the second optical element; and
a soldering material connecting the second optical element to the connecting element.

9. The electronic device as claimed in claim 8, wherein the connecting element supports the first optical element.

10. An electronic device, comprising:
an electronic component; and
a connecting structure comprising an optical element,
wherein the connecting structure is configured to solder to the electronic component and to conduct an optical transmission between the electronic component and the optical element.

11. The electronic device as claimed in claim 10, wherein the connecting structure comprises a portion protruding beyond a side surface of the electronic component, and the optical element is adjacent to the side surface and connected to the portion of the connecting structure.

12. The electronic device as claimed in claim 11, wherein the optical element is spaced apart from the side surface of the electronic component.

13. The electronic device as claimed in claim 10, wherein the electronic component comprises an optical channel configured to optically couple to the optical element.

14. The electronic device as claimed in claim 13, wherein a portion of the connecting structure is disposed over the optical channel.

15. An electronic device, comprising:
a first electronic component;
a second electronic component disposed above and electrically connected to the first electronic component; and
an optical element supported by the second electronic component and configured to optically couple with the first electronic component.

16. The electronic device as claimed in claim 15, further comprising a carrier supporting the first electronic component and spaced apart from the optical element.

17. The electronic device as claimed in claim 16, further comprising a third electronic component disposed in a gap between the carrier and the optical element.

18. The electronic device as claimed in claim 17, wherein the third electronic component comprises a passive component.

19. The electronic device as claimed in claim 16, wherein the second electronic component is electrically connected to the carrier through the first electronic component.

20. The electronic device as claimed in claim 19, further comprising a third electronic component disposed over the first electronic component and electrically connected to the second electronic component through the first electronic component.
